(19) United States
(12) Patent Application Publication
(10) Pub. No.: US 2013/0035891 A1
(43) Pub. Date: Feb. 7, 2013

(54) TEST PATTERN GENERATOR, METHOD OF GENERATING TEST PATTERN, AND COMPUTER READABLE STORAGE MEDIUM HAVING TEST GENERATION PROGRAM STORED THEREON

(71) Applicant: Daisuke Maruyama, Sagamihara (JP)

(72) Inventor: Daisuke Maruyama, Sagamihara (JP)

(73) Assignee: FUJITSU LIMITED, Kawasaki-shi (JP)

(21) Appl. No.: 13/463,885

(22) Filed: May 4, 2012

(30) Foreign Application Priority Data
Aug. 2, 2011 (JP) 2011-169010

(51) Int. Cl. G06F 19/00; G01R 31/3183

(52) U.S. Cl. 702/119

(57) ABSTRACT

A second computing device determines whether or not a conflict occurs wherein at least two of a plurality of first computing devices set different request values to an input point to which a request value is to be set, based on the request value stored in the request value buffer. When it is determined by the second computing device that a conflict occurs wherein one of the plurality of first computing devices is about to set a request value different from a request value that is set to that input point by another first computing device, the one of the first computing devices stops setting the request value. This prevents any increase in the test pattern count due to parallel processing.

### CROSS-REFERENCE TO RELATED APPLICATION

This application is based upon and claims the benefit of priority of the prior Japanese Application No. 2011-169010, filed on Aug. 2, 2011 in Japan, the entire contents of which are hereby incorporated by reference.

### FIELD

The embodiments discussed herein are related to a test pattern generator, a method of generating a test pattern, and a computer readable storage medium having a test generation program stored thereon.

### BACKGROUND

In general, in the final stage of production of integrated circuits, such as large scale integrations (LSIs), manufactured LSIs are tested by a tester using certain test patterns. Referring to the flowchart depicted in FIG. 11 (Steps S101 to S113), an example of a typical test process for LSIs will be described. After wafers on which LSIs are fabricated are ejected (Wafer out; Step S101), the LSIs on the wafers are tested by a tester using a test pattern stored in a database 126 (Step S102). If the pass-fail result of an LSI in during test (Step S103) is “fail”, the LSI is discarded (Step S104). Otherwise, the pass-fail result of an LSI in during test (Step S103) is “pass”, that LSI is diced and packaged (Step S105).

Thereafter, the packaged LSI is tested by a tester using a test pattern stored in the database 126 (Step S106). If the pass-fail result of a packaged LSI in during test (Step S107) is “fail”, the LSI is discarded (Step S108). Otherwise, the pass-fail result of a packaged LSI in during test (Step S107) is “pass”, a load test (burn-in process) is performed on that LSI (Step S109).

Finally, the LSI after the load test is tested by a tester using a test pattern stored in the database 126 (Step S110). If the pass-fail result of an LSI in during test (Step S111) is “fail”, the LSI is discarded (Step S112). Otherwise, the pass-fail result of an LSI in during test (Step S111) is “pass”, that LSI is send to the subsequent assembly step (Step S113).

A test pattern includes a set of input states to be entered to a circuit to be examined (hereinafter, such a circuit is referred to as an examined circuit), such as an LSI, and a set of output states to be output from the examined circuit when the respective input states are entered to the LSI.

Each input state is a value to be set to an input point in an examined circuit (hereinafter, such a value is referred to as a request value) in order to detect possible failures that may occur in the examined circuit. Input states are generated by an automatic test pattern generator (ATPG). Example of such input points include data-in terminals (primary-input) and scan latches (scan-input), for example.

Each output state is an expected value of a response that is returned from the examined circuit when a corresponding input state is given to an input point in the examined circuit in a failure simulator for performing a simulation.

In a test using a test pattern as described above, a request value is set to an input point in an examined circuit to operate that examined circuit, thereby obtaining a response value from the examined circuit. If the obtained response value matches the expected value, the test result is determined as “pass”. Otherwise, if the obtained response value does not match the expected value, the test result is determined as “fail”. Such tests are performed in Steps S102, S106, and S110 in the test process depicted in FIG. 11.

In the meantime, an examined circuit, such as an LSI, has been scaled up, which results in an increase in the test pattern count, eventually causing an increased memory consumption during a test and an extended test time. For example, since three tests are performed in the test process depicted in FIG. 11 (refer to Steps S102, S106, and S110), an increase in the test pattern count apparently represents an extended test process time, which eventually leads to an increased production cost.

Further, the scaling up of examined circuits also increases the requirement for computer resources (memory usage and computation time) for generating test patterns, and improvements for techniques to generate test patterns have been demanded, for suppressing such an increase. One of such improvements involves dividing targets (e.g., failure sets and circuit) for generating test patterns in order to reduce their sizes, followed by parallel processing on the divided targets on multiple computers. There are two typical techniques for generating test pattern involving division: the failure division and circuit division techniques.

In the failure division technique, a circuit model is supplied in which only a failure set is divided without dividing a net list, and test patterns for circuit models are generated by multiple computers in parallel and the generated test patterns for the circuit models are then merged.

In the circuit division technique, a circuit model is supplied in which both a net list and a failure set belonging in the net list are divided, and test patterns for circuit models are generated by multiple computers in parallel and the generated test patterns for the circuit models are then merged.

As one technique to generate test patterns for divided circuits by multiple computers in parallel, one technique is also proposed, in which a circuit is divided by back-tracing on fixed-value signal lines (fixed-value signal lines having fixed logic values) that are extracted using learning and the like, for example, thereby enhancing independence among the divided circuits (Patent Literature 1). In another proposed technique, in order to speed up static pattern compaction, each computer independently switches between an algorithmic test generation (ATG) and compaction of partial test pattern sets temporarily stored in the computer (Patent Literature 2).

The above-described techniques for processing divided targets by multiple computers in parallel can suppress an increase in the memory consumption and the test time for test pattern generation.

However, the parallel processing may increase the test pattern count, as an overhead related to the parallel processing, for the following reason. Except for a particular circuit, when an examined circuit is divided, a part of divided multiple circuits overlap, having a common input point. On the other hand, in the above-described conventional techniques for generating test patterns in parallel processing, test pattern generation processes for the respective divided circuits are done independently from computer to computer. If test patterns are generated in parallel by multiple computers which operate independently from each other, for multiple divided circuits having a common input point, a conflict may occur. As used herein, a conflict (mismatch or collision) is a situation wherein computers set different request values to a single input point to be requested. Two or more conflicting test patterns in which different request values are set to a single input point cannot be merged, and they are generated as separate test patterns. This causes an increase in the test pattern count.
Patent Literature 1: Japanese Laid-open Patent Publication No. HEI 7-234266
Patent Literature 2: Japanese Laid-open Patent Publication No. 2003-222658

### SUMMARY

A test pattern generator of the present disclosure is a test pattern generator that generates a test pattern for each of a plurality of divided circuits defined by dividing an integrated circuit into a plurality of circuits using a plurality of computing devices, the test pattern generator including a plurality of first computing devices and a second computing device. The plurality of first computing devices, each generate a test pattern for one of the divided circuits. The second computing device controls the generation of the test patterns by the plurality of first computing devices, and includes a request value buffer for storing a request value for each input point used for detecting a failure in an examined circuit in each divided circuit. The second computing device determines whether or not a conflict occurs wherein at least two of the plurality of first computing devices set different request values to an input point to which a request value is to be set, based on the request value stored in the request value buffer, and when it is determined by the second computing device that a conflict occurs wherein one of the plurality of first computing devices is about to set a request value different from a request value that is set to that input point by another first computing device, the one of the first computing devices stops setting the request value.

A method of generating a test pattern of the present disclosure is a method of generating a test pattern for each of a plurality of divided circuits defined by dividing an integrated circuit, using a plurality of first computing devices, each generating a test pattern for one of the divided circuits, and a second computing device that controls the generation of the test patterns by the plurality of first computing devices. In the method, the second computing device stores, in a request value buffer, a request value for each input point used for detecting a failure in an examined circuit in each divided circuit, and determines whether or not a conflict occurs wherein at least two of the plurality of first computing devices set different request values to an input point to which a request value is to be set, based on the request value stored in the request value buffer. When it is determined by the second computing device that a conflict occurs wherein one of the plurality of first computing devices is about to set a request value different from a request value that is set to that input point by another first computing device, the one of the first computing devices stops setting the request value.

A computer readable storage medium of the present disclosure is a computer readable storage medium having a test generation program stored thereon, that makes a compute to function, in order to generate a test pattern for each of a plurality of divided circuits defined by dividing an integrated circuit, as one of a plurality of first computing devices, each generating a test pattern for one of the divided circuits, or a second computing device that controls the generation of the test patterns by the plurality of first computing devices. The program makes the computer functioning as the one of the second computing device, store, in a request value buffer, a request value for each input point used for detecting a failure in an examined circuit in each divided circuit, and determine whether or not a conflict occurs wherein at least two of the plurality of first computing devices set different request values to an input point to which a request value is to be set, based on the request value stored in the request value buffer. Further, the program makes the computer functioning as the one of the first computing devices, when it is determined by the second computing device that a conflict occurs wherein one of the plurality of first computing devices is about to set a request value different from a request value that is set to that input point by another first computing device, stop setting the request value.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF THE DRAWINGS

FIG. 1 is a block diagram illustrating hardware and functional configurations of a test pattern generator of the present embodiment;

FIG. 2 is a diagram illustrating a technique to divide a circuit in the present embodiment;

FIG. 3 is a diagram illustrating the technique to divide a circuit in the present embodiment, and an overlap region in a circuit divided using the technique;

FIG. 4 is a flowchart illustrating an operation of the test pattern generator depicted in FIG. 1;

FIG. 5 is a flowchart illustrating the procedure of the circuit division processing depicted in FIG. 4;

FIG. 6 is a flowchart illustrating the synchronization processing of requested values depicted in FIG. 4;

FIGS. 7A to 7C are diagrams illustrating, in a concrete manner, an example of an operation of the test pattern generator of the present embodiment, in a comparison with an operation of a conventional technique;

FIG. 8 is a diagram illustrating an asynchronous communication of request values between slaves and a master in the present embodiment;

FIG. 9 is a block diagram illustrating a functional configuration of a typical test pattern generator;

FIG. 10 is a flowchart illustrating an operation of the test pattern generator depicted in FIG. 9; and

FIG. 11 is a flowchart illustrating a typical LSI test process.

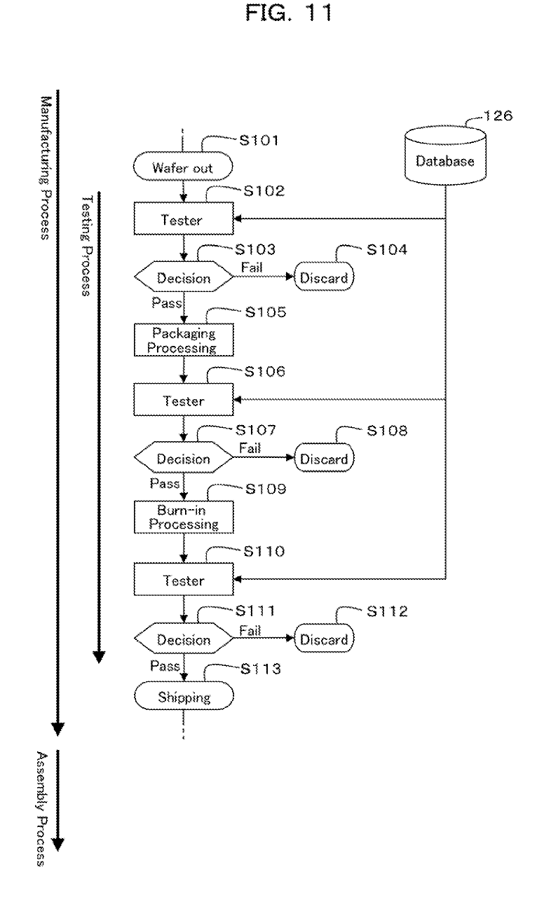

### DESCRIPTION OF THE PREFERRED EMBODIMENTS

Hereunder is a description of embodiments with reference to the drawings.

### (1) Typical Test Pattern Generator

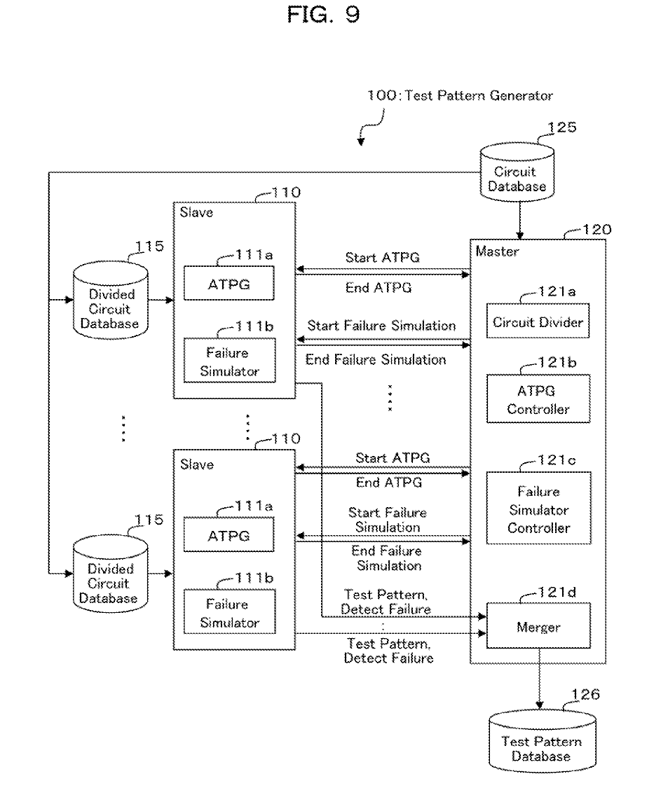

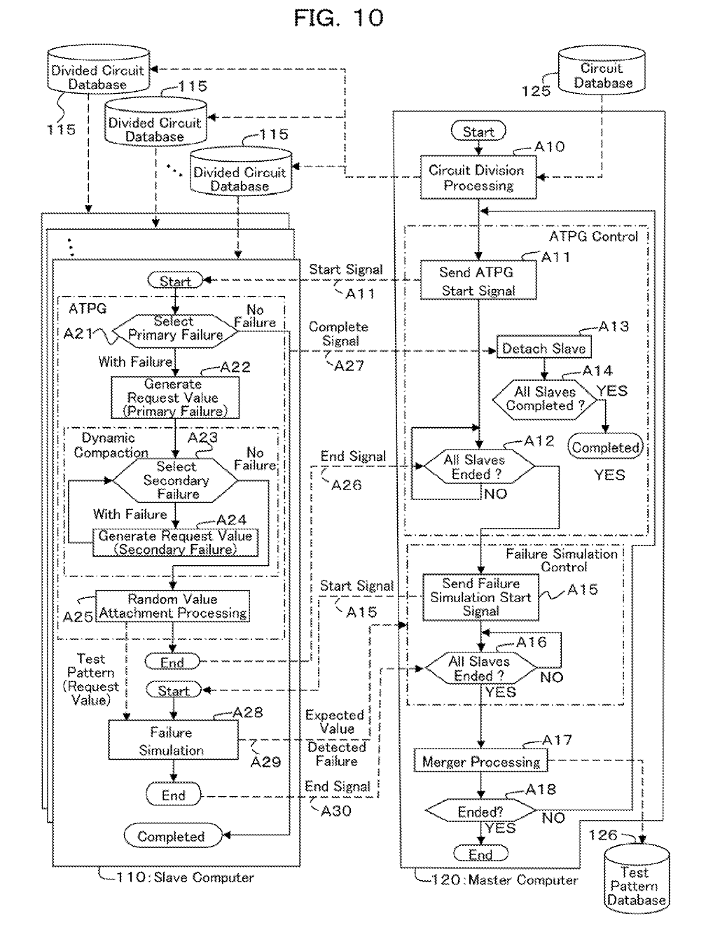

Firstly, referring to FIGS. 9 and 10, the functional configuration and operation of a typical test pattern generator 100 which generates test patterns with parallel processing will be described. FIG. 9 is a block diagram illustrating the functional configuration of the typical test pattern generator 100, and FIG. 10 is a flowchart illustrating an operation of the test pattern generator 100 depicted in FIG. 9.

The typical test pattern generator 100 depicted in FIG. 9 divides a circuit to be examined (hereinafter, refereed to as an examined circuit), such as an LSI, into multiple circuits, and generates test patterns for the respective divided circuits using multiple computers 110 and 120. The test pattern generator 100 includes multiple slave computers (hereinafter, simply referred to as “slaves”) 110 and a single master computer (hereinafter, simply referred to as the “master”) 120.

The master 120 is provided with a circuit database 125 and a test pattern database 126. The circuit database 125 stores a net list, failure information, and the like, for the entire examined circuit. The test pattern database 126 stores the test pattern, the detected failure, and the like, for the examined circuit as a whole, merged by a merger 121d, which will be described later.

Each slave 110 is provided with a divided circuit database 115. The divided circuit database 115 stores a net list, failure information, and the like, for one circuit divided by the circuit divider 121a, which will be described later, and assigned to one slave 110.

The divided circuits are assigned to the respective slaves 110 for generating test patterns for the respective assigned circuits in parallel, and each slave 110 includes functions of an ATPG 111a and a failure simulator 111b.

The ATPG 111a generates, for its corresponding divided circuit, a request value to be set to an input point in the circuit to detect any failure in that circuit, based on information in the divided circuit database 115. The ATPG 111a is activated in response to a start signal from the master 120, and executes processing (Steps A21 to A27), which will be described later with reference to FIG. 10.

The failure simulator 111b is activated in response to a start signal from the master 120, and executes a simulation by giving a request value generated by the ATPG 111a to the input point in the circuit, thereby obtaining an expected value, which is a response for that circuit.

The request value obtained by the ATPG 111a and the expected value obtained by the failure simulator 111b are sent from each slave 110 to the master 120, as a test pattern for the corresponding circuit. At the same time, information on any failure detected with the test pattern, i.e., any detected failure, is also sent from each slave 110 to the master 120.

The master 120 controls the test pattern generations by the multiple slaves 110, and includes functions of a circuit divider 121a, an ATPG controller 121b, a failure simulator controller 121c, and a merger 121d.

The circuit divider 121a divides an examined circuit into multiple circuits, based on information about the examined circuit as a whole, stored in the circuit database 125. Note that the divided multiple circuits may overlap partially and may have common input point(s). The information about a divided circuit is stored in a divided circuit database 115 in a slave 110 which is assigned to process that circuit.

The ATPG controller 121b controls operations of the respective ATPGs 111a in the respective slaves 110, and instructs to start generation of a request value to the ATPGs 111a in the slaves 110. Specifically, the ATPG controller 121b performs processing (Steps A11 to A14) which will be described later with reference to FIG. 10.

The failure simulator controller 121c controls operations of the respective failure simulators 111b in the slaves 110, and instructs the failure simulators 111b in the slaves 110 to start a failure simulation. Specifically, the failure simulator controller 121c performs processing (Steps A15 and A16) which will be described later with reference to FIG. 10.

The merger 121d merges test patterns for the divided circuits received from the failure simulators 111b in the slaves 110 to generate a test pattern for the examined circuit as a whole, and stores it in the test pattern database 126.

Next, referring to the flowchart depicted in FIG. 10 (Steps A10 to A30), the operation of the typical test pattern generator 100 depicted in FIG. 9 will be described.

Firstly, the circuit divider 121a in the master 120 divides a circuit to be examined stored in the circuit database 125, into multiple circuits (Step A10). The information about the divided circuits is stored in a divided circuit database 115 in a slave 110 which is assigned to process that circuit. The ATPG controller 121b then sends an ATPG start signal for instructing the ATPGs 111a in all of the slaves 110 to start generation of a request value (Step A11).

The ATPG 111a in each slave 110, in response to receiving the ATPG start signal from the master 120, starts generation of a request value, by selecting a primary failure in the corresponding divided circuit (the “With Failure” route from Step A21). The ATPG 111a generates a request value to be set to the input point in that divided circuit for detecting the selected primary failure (Step A22), and executes a dynamic compaction. In the dynamic compaction, a secondary failure is selected (the “With Failure” route from Step A23) under the condition of the setting of the request value for detecting the primary failure, and a request value to be set to the input point in the divided circuit for detecting the selected secondary failure is generated (Step A24). By repeating the processing in Steps A23 and A24, request values for detecting the secondary failure are superimposed, under the condition of the setting of the request value for detecting the primary failure. If there is no secondary failure to be superimposed any more, that is, there is no secondary failure that can be selected (the “No Failure” route from Step A23), random value attachment processing is executed to attach a random value to an input point to which no request value has been set (Step A25). After the random value attachment processing, the ATPG 111a terminates the processing, and sends an ATPG end signal to the master 120 (Step A26). The request value set for the divided circuit obtained in the processing in Steps A21 to A25 is passed to the failure simulator 111b.

In the meantime, after sending the ATPG start signal, the ATPG controller 121b in the master 120 waits until ATPG end signals are sent from all of the slaves 110 (Step A12). Once receiving ATPG end signals from all of the slaves 110 (the YES route from Step A12), the ATPG controller 121b terminates the processing, and the failure simulator controller 121c is activated. In response, the failure simulator controller 121c sends a start signal to the failure simulators 111b in all of the slaves 110 to instruct a start of a failure simulation (Step A15).

Each failure simulator 111b in the slaves 110 initiate a failure simulation, in response to receiving the start signal for a failure simulation from the master 120. In other words, the failure simulator 111b gives a request value generated by the corresponding ATPG 111a to an input point in the divided circuit to perform the simulation, thereby obtaining an expected value that is a response for the divided circuit (Step A28). The request value obtained by the ATPG 111a and the expected value obtained by the failure simulator 111b are sent from each slave 110 to the master 120 as a test pattern for the divided circuit. In addition, information about any detected failure is also sent from each slave 110 to the master 120 (Step A29). After sending the test pattern and the detected failure, the failure simulator 111b terminates the processing, and sends a failure simulation end signal to the master 120 (Step A30).

After sending the start signal of a failure simulation, the failure simulator controller 121c in the master 120 waits until failure simulation end signals are sent from all of the slaves 110 (Step A16). Once receiving failure simulation end signals from all of the slaves 110 (the YES route from Step A16), the failure simulator controller 121c terminates the processing, and the merger 121d is activated. In response, the merger 121d merges the test patterns for the divided circuits received from the respective slaves 110 to generate a test pattern for the examined circuit as a whole, and stores it in the test pattern database 126 (Step A17). The master 120 returns to Step A11 to repeat processing as described above until an end condition is met (until the determination in Step A18 produces YES).

Here, the processing depicted in FIGS. 9 and 10 by the ATPG 111a in each slave 110 is a closed processing independently executed by that slave 110, and what the master 120 does is merely sending an ATPG start signal to the slaves 110 and receiving ATPG end signals from the slaves 110. In other words, the processing by the ATPG 111a in each slave 110 is independently done, and the slaves 110 and the master 120 make no communication with each other from the beginning until the end of the processing. Accordingly, as described above, if test patterns are generated in parallel by slaves 110 which operate independently from each other, for multiple divided circuits having a common input point, a conflict (mismatch or collision) may occur. As used herein, a conflict is a situation wherein slaves 110 set different request values to a single input point to be requested, as set forth previously. Two or more conflicting test patterns in which different request values are set to a single input point cannot be merged by the merger 121d, which may increase the test pattern count since they are generated as separate test patterns.

If the ATPG 111a in each slave 110 generates request values for all failures assigned to the divided circuit and there is no failure which can be selected (the “No Failure” route from Step A21), the slave 110 performs the following operation. More specifically, the slave 110 sends a complete signal to the master 120 (Step A27), changes its status to completion, and terminates its processing without performing the processing by the failure simulator 111b. In response to receiving the complete signal, the master 120 detaches a slave 110 which has sent a complete signal (Step A13) and waits until complete signals are sent from all of the slaves 110 (Step A14). In response to receiving complete signals from all of the slaves 110 (the YES route from Step A14), the master 120 terminates the processing without activating the failure simulator controller 121c.

The primary purpose of each slave 110 is generation of a test pattern for failures assigned to a divided circuit. Hence, if there is no failure to be processed any more in slave 110, terminating processing of that slave 110 by performing the above-described completion operation (Steps A27, A13, and A14) is quite reasonable. However, since the slave 110 which terminates its processing also stops a failure simulation, no expected value related to the divided circuit assigned to that slave 110 can be obtained any more.

Some LSIs include a test system having a built-in self test (BIST)-aided scan test (BAST) circuit that requires masking of an undefined value included in an expected value. When completion operation (Steps A27, A13, and A14) is performed on an LSI including such a test system, as an examined circuit, an overhead due to the masking of an undefined value resulting from parallel processing, i.e., an increase in the test pattern count, may occur.

Here, a BAST circuit will be described briefly. A BAST circuit is used for test data compaction, and includes a pseudo random value generator (linear feedback shift register: LFSR), a signature generator (multiple input signature register: MISR), an inversion block, an undefined value mask block, a decoder block, and the like. A BAST circuit is disclosed in the Transactions of the Institute of Electronics, Information and Communication Engineers D-1, Vol. J88-D-1, No. 6, pp. 1012-1022, for example, while an MISR is disclosed in Japanese Laid-open Patent Publication No. HEI 8-15382, for example.

An MISR is one type of pseudo random value generators using an LFSR, wherein a signature, which is a random value, varies depending on a given input value. More specifically, a signature varies depending on whether a failure included in a scan-out value is observed or not, by giving the scan-out value as an input value to the MISR during a tester measurement. Accordingly, whether a failure is observed or not can be determined, by comparing a signature in the absence of a failure, resulting from a computation performed in advance, and a signature obtained in an actual tester measurement, without need of directly comparing long scan-out values. In other words, since whether a failure is observed or not can be determined by comparing short signatures, without comparing long scan-out values, test patterns can be compacted.

Note that if an undefined value is included in a scan-out value entered to an MISR when calculating a signature in the absence of a failure in advance, the undefined value must be masked. The MISR sets an exclusive OR between the current signature stored in a flip-flop (FF) and an input value, as the next signature. Hence, if an undefined value is included in an input value, that undefined value is stored in the FF. Thereafter, the undefined value spreads in the progress of cycles, and eventually the signature cannot maintain its expected value. In other words, the signature is destroyed. For example, in order to mask an undefined value in a certain time frame, clocks corresponding to the number of scan chains are required be applied for masking undefined values, and the applied clocks define an overhead increasing the test pattern count (refer to Table 2 in the Transactions of the Institute of Electronics, Information and Communication Engineers D-1, Vol. J88-D-1, No. 6, pp. 1012-1022 described above).

### (2) Test Pattern Generator of the Present Embodiment

As described above, in the test pattern generator 100 depicted in FIGS. 9 and 10, test patterns for divided circuits are generated in parallel by ATPGs in multiple slaves independently operating in parallel and the generated test patterns are then merged.

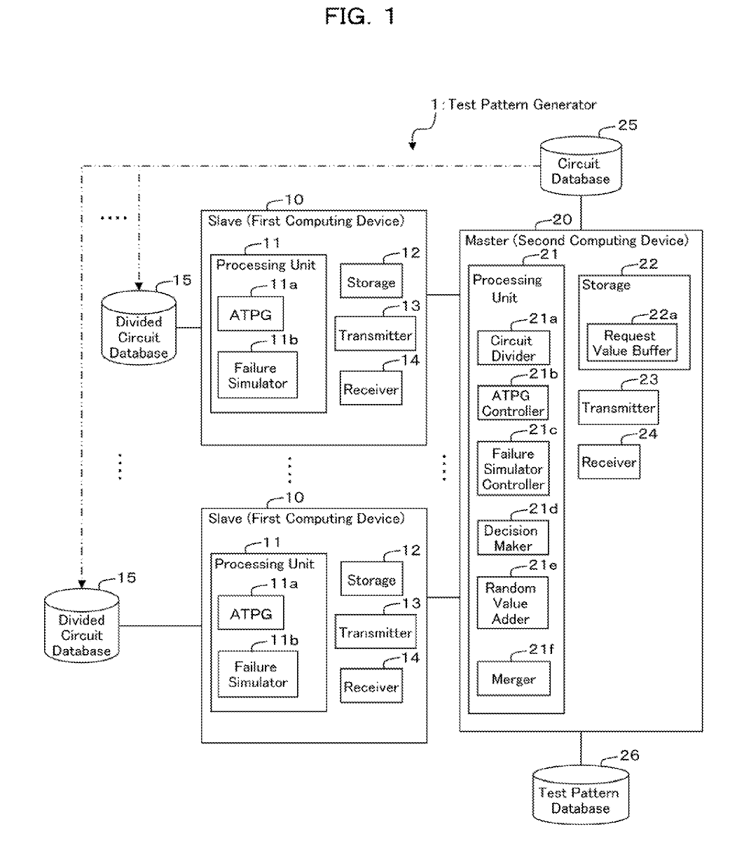

In contrast, as will be described later, a test pattern generator 1 of the present embodiment (refer to FIG. 1) has a mechanism to avoid any conflict of request values to be set to a common input point among divided circuits, by communicating between a master and a slave during generation processing of a request value by ATPGs, rather than allowing a slave to operate fully independently.

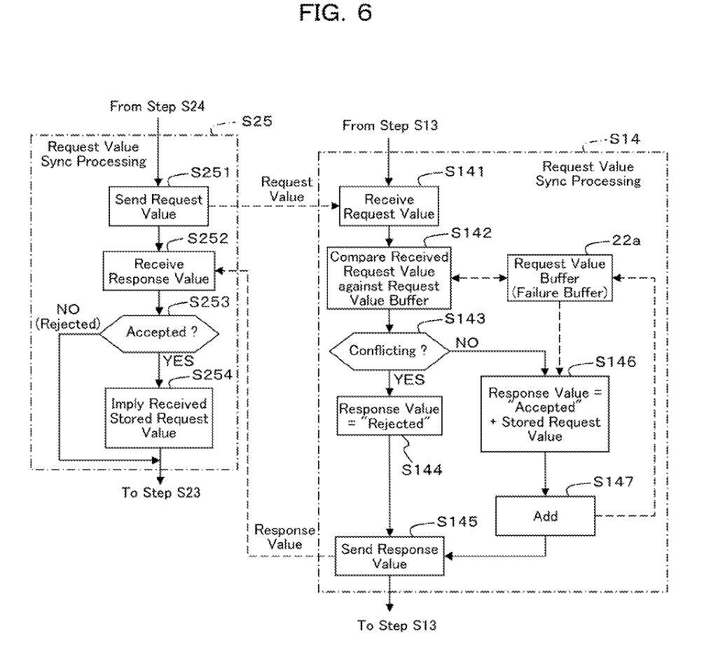

In this mechanism, request values are synchronized (matched to the same value) among multiple slaves by a request value buffer 22a (refer to FIGS. 1 and 6) in a master. That is, request values of the slaves are synchronized (matched to the same value) via the master (request value buffer 22a). Hence, even when test patterns are generated in parallel processing by multiple slaves, a circuit state that is comparable to a test pattern generation in a single computing device is maintained via the request value buffer 22a, which suppresses any increase in the test pattern count due to the parallel processing.

Further, the test pattern generator 1 of the present embodiment, which will be described later, in a slave which has no more failure to be selected, request value generation processing by the ATPG is skipped, while continuing the failure simulation processing to obtain an expected value, in order to support a pattern compaction circuit using the MISR. This prevents any increase in the test pattern count due to masking of undefined values.

### (2-1) Configuration of Test Pattern Generator of the Present Embodiment

FIG. 1 is a block diagram illustrating hardware and functional configurations of a test pattern generator 1 of the present embodiment.

Similar to the test pattern generator 100 described above, the test pattern generator 1 depicted in FIG. 1 divides a circuit to be examined (hereinafter, refereed to as an examined circuit), such as an LSI, into multiple circuits, and generates test patterns for the respective divided circuits using multiple computers (computing devices) 10 and 20. The test pattern generator 1 includes multiple slave computers (first computing device; hereinafter, simply referred to as “slaves”) 10 and a single master computer (second computing device; hereinafter, simply referred to as the “master”) 20.

The master 20 is provided with a circuit database 25 and a test pattern database 26. The circuit database 25 stores a net list, failure information, and the like, for the entire examined circuit. The test pattern database 26 stores the test pattern, the detected failure, and the like, for the examined circuit as a whole, merged by a merger 21d, which will be described later.

Each slave 10 is provided with a divided circuit database 15. The divided circuit database 15 stores a net list, failure information, and the like, for one circuit divided by the circuit divider 21a, which will be described later, and assigned to one slave 10.

The divided circuits are assigned to the respective slaves 10 for generating test patterns for the respective assigned circuits in parallel, and each slave 10 includes a processing unit 11 (central processing unit: CPU), a storage 12, a transmitter 13, and a receiver 14.

The processing unit 11 functions as an ATPG 11a and a failure simulator 11b, which will be described later, by executing certain programs, including a test pattern generation program.

The storage 12 stores such certain programs, and various types of information related to processing by the ATPG 11a and failure simulator 11b.

The transmitter 13 is controlled by the processing unit 11, and sends various types of information (such as a request value, an end signal, a complete signal, a detected failure, an expected value) to the master 20.

The receiver 14 receives various types of information such as a start signal, a response value, a request value of which a conflict is suppressed, hereinafter, such a request value is referred to as a conflict-suppressed request value) from the master 20, and passes it to the processing unit 11.

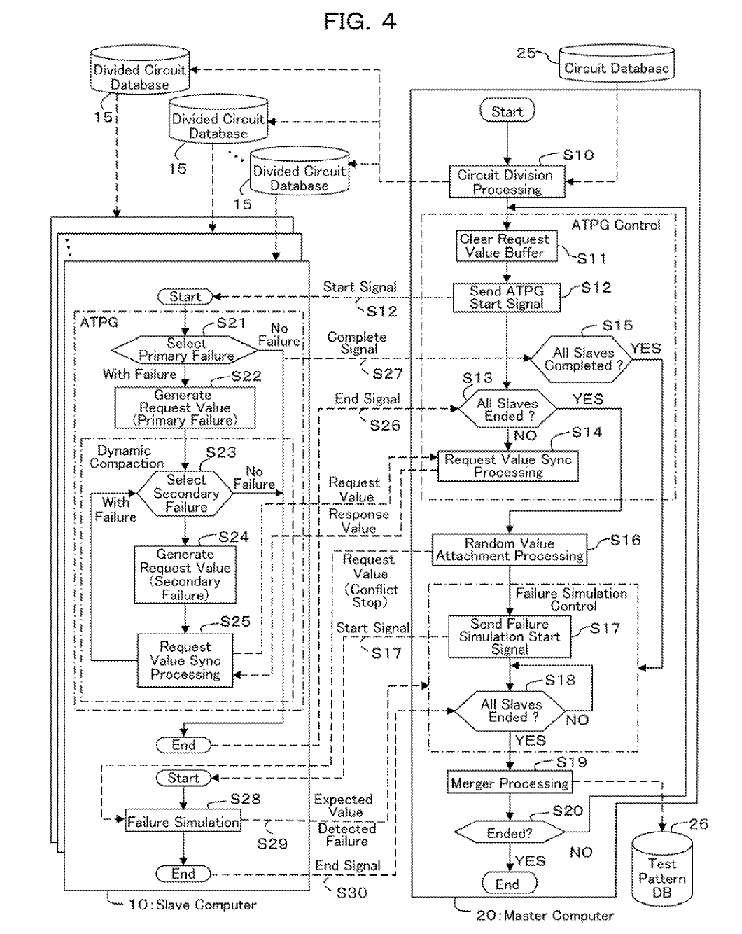

The ATPG 11a generates, for its corresponding divided circuit, a request value to be set to an input point in the divided circuit to detect any failure in that divided circuit, based on information in the divided circuit database 15. The ATPG 11a is activated in response to a start signal from the master 20, and executes processing (Steps S21 to S27, and Steps S251 to S254), which will be described later with reference to FIGS. 4 and 6.

The failure simulator 11b is activated in response to a start signal from the master 20, and executes a simulation by giving a conflict-suppressed request value received from the master 20, to the input point in the divided circuit, thereby obtaining an expected value, which is a response for that divided circuit, as will be described below. The expected value obtained by the failure simulator 11b is sent from each slave 10 to the master 20. At the same time, information on any failure detected with the test pattern, i.e., any detected failure, is also sent from each slave 10 to the master 20.

The master 20 controls the test pattern generations by the multiple slaves 10, and includes a processing unit (CPU) 21, a storage 22, a transmitter 23, and a receiver 24.

The processing unit 11 functions as a circuit divider 21a, an ATPG controller 21b, a failure simulator controller 21c, a decision maker 21d, a random value adder 21e, and a merger 21f, which will be described later, by executing certain programs, including the test pattern generation program.

The storage 22 stores such certain programs, and various types of information related to processing in the circuit divider 21a, the ATPG controller 21b, the failure simulator controller 21c, the decision maker 21d, the random value adder 21e, and the merger 21f. The storage 22 includes a request value buffer 22a. As will be described below, the request value buffer 22a stores a request value for each input point to be requested, included in a circuit divided by the circuit divider 21a.

The transmitter 23 is controlled by the processing unit 21, and sends various types of information (such as a start signal, a response value, a conflict-suppressed request value) to each slave 10.

The receiver 24 receives various types of information (such as a request value, an end signal, a complete signal, a detected failure, an expected value) from each slave 10, and passes it to the processing unit 21.

The circuit divider 21a divides an examined circuit into multiple circuits, based on information about the examined circuit as a whole, stored in the circuit database 25. Note that the divided multiple circuits may overlap partially and may have common input point(s). The information about a divided circuit is stored in a divided circuit database 15 in a slave 10 which is assigned to process that circuit.

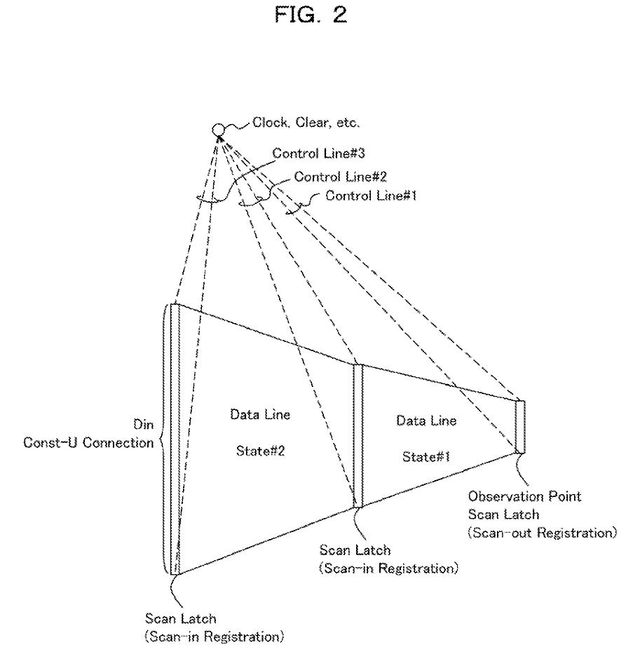

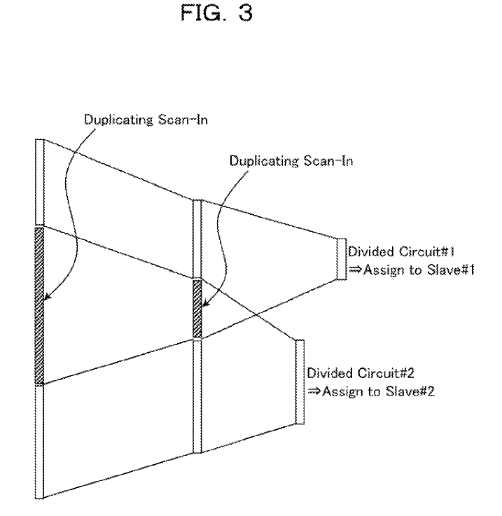

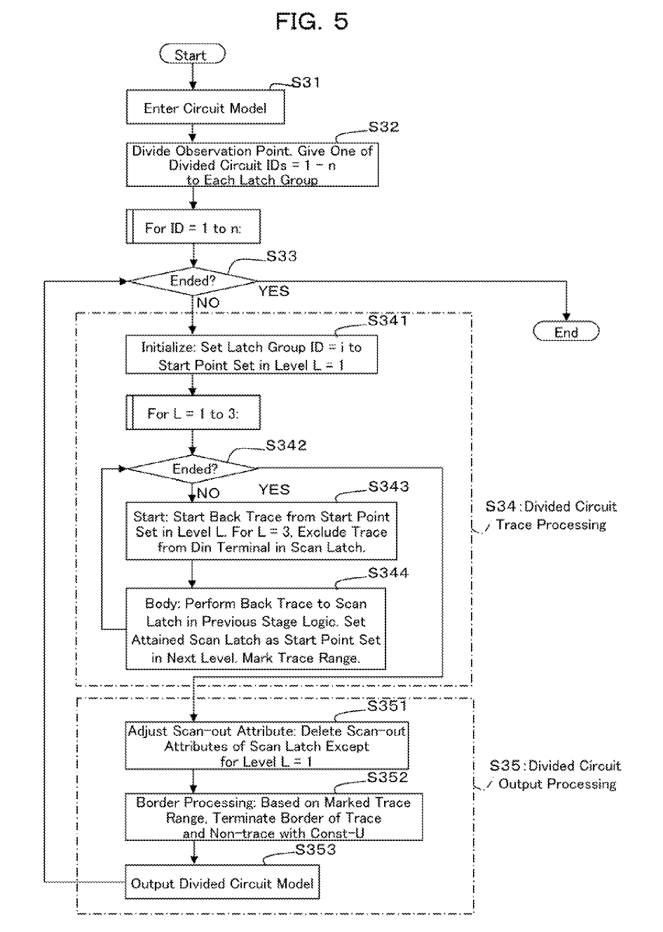

Now, referring to FIGS. 2 and 3, a technique to divide a circuit by the circuit divider 21a of the present embodiment will be described. FIG. 2 is a diagram illustrating a technique to divide a circuit of the present embodiment, and FIG. 3 is a diagram illustrating the technique to divide a circuit in the present embodiment, and an overlap region in a circuit divided using the technique. The details of the technique to divide a circuit by the circuit divider 21a will be described later with reference to FIG. 5.

Unless each divided circuit is a model which ensures the accuracy of the circuit state of the slave 10 corresponding to that divided circuit and its expected value, it is difficult to maintain the circuit state and the expected value in the manner similar to when a test pattern is generated for a single computing device in the test pattern generator 1 as a whole. For that reason, the circuit divider 21a performs a circuit division as follows.

As depicted in FIGS. 2 and 3, the circuit divider 21a divides an observation point scan latch in an examined circuit, an output state of which is to be observed as an expected value, into multiple latch groups, and assigns these latch groups to multiple divided circuits (divided circuits #1 and #2 in FIG. 3). At this time, there is no observation point scan latch that overlaps in multiple divided circuits. FIG. 2 back-traces from one latch group, whereas FIG. 3 back-traces from two latch groups to identify two divided circuits having a common input point.

The circuit divider 21a then divides the examined circuit into multiple circuits corresponding to the multiple latch groups by back-tracing from each of the divided latch groups, as depicted in FIG. 3, and assigns the divided multiple circuits to the multiple slaves 10 (refer to the slave #1 and #2 in FIG. 3). In this manner, the validity of the expected value upon a circuit division is endured by performing the circuit division by back-tracing from the observation point scan latch side.

In addition, the circuit divider 21a back-traces data lines and control lines with an additional one stage as compared to a typical static test from each of the divided latch groups, in order to support a double pulse delay function test (WDFT). More specifically, the depth of the back trace by the circuit divider 21a is two stages (state #1 and #2) for the data lines, and three stages (control line #1 to #3) for the control lines, such as the clock and clear, as depicted in FIG. 2.

Note that the data terminal Din for the scan latch, which is an input point attained in the back trace, undergoes boundary processing, as will be described later with reference to FIG. 5, and is connected to a constant-uncontrollable value (Const-U).

Further, as depicted in FIG. 3, in general, when a circuit is divided with a back trace from a certain observation point scan latch, a single input (see the overlapped scan-in in FIG. 3) may be registered to separate divided circuits. The test pattern count may be increased, if separate request values are set to respective slave 10 corresponding to different divided circuits for a common input (overlapped scan-in) as depicted in FIG. 3, in other words, if a conflict occurs.

Hereinafter, a configuration for avoiding such a conflict of request values in a common input with synchronization processing of request values, will be described with reference to FIG. 1.

The ATPG controller 21b controls operations of the respective ATPGs 11a in the slaves 10, and sends an ATPG start signal instructing to start generation of a request value, to the ATPGs 11a in the slaves 10 via the transmitter 23. Specifically, the ATPG controller 21b performs processing (Steps S11 to S15 and S141 to S147) which will be described later with reference to FIGS. 4 and 6, in cooperation with a decision maker 21d, which will be described later.

The failure simulator controller 21c controls operations of the respective failure simulators 11b in the slaves 10, and sends a start signal instructing to start a failure simulation, to the failure simulators 11b in the slaves 10, via the transmitter 23. Specifically, the failure simulator controller 21c performs processing (Steps S17 and S18) which will be described later with reference to FIG. 4.

The decision maker 21d determines whether or not a conflict occurs wherein multiple slaves 10 set different request values to the same input point to be requested, based on a request value stored in the request value buffer 22a.

Each slave 10 inquires the decision maker 21d in the master 20, as to whether or not a conflict occurs, via the transmitter 13 and the receiver 24, when the ATPG 11a is about to set a request value to an input point to be requested included in a divided circuit. As used herein, a conflict refers to a situation wherein a request value that is set to a point by an ATPG 11a in a slave 10 differs from a request value set by another slave 10 to that input point.

In response to receiving an inquiry about a conflict of the request value to be set, from a slave 10, the decision maker 21d makes a determination for that inquiry, based on request values stored in the request value buffer 22a. In other words, the decision maker 21d checks the request value related to the inquiry against the request values stored in the request value buffer 22a.

More specifically, the decision maker 21d checks a bit corresponding to the input point, to which the request value related to the inquiry is set, in the request value buffer 22a, and compares the request value stored in that bit, against the request value related to the inquiry.

If the request values match or no request value has not yet been set to the corresponding bit, the decision maker 21d determines that no conflict occurs (no conflict). Otherwise, if a value different from the request value related to the inquiry is set to the corresponding bit, the decision maker 21d determines that a conflict occurs (conflicting). In other words, if “1” is set to the request value related to the inquiry while “0” is set to the corresponding bit, or if “0” is set to the request value related to the inquiry while “1” is set to the corresponding bit, it is determined that a conflict occurs (conflicting).

If the decision maker 21d determines that a conflict occurs, the decision maker 21d sends a response indicating that a conflict occurs (reject) as a result of the inquiry, to the slave 10 making the inquiry, via the transmitter 13 and the receiver 24. The slave 10 receiving that reject response stops setting that request value.

If the decision maker 21d determines that a conflict does not occur, the decision maker 21d reflects the request value related to the inquiry to the corresponding request value stored in the request value buffer 22a. In other words, the request value related to the inquiry is added to the request value buffer 22a, as a request value set to the corresponding input point. The decision maker 21d sends a response indicating that no conflict occurs (accept) as a result of the inquiry and the request value for each input point stored in the request value buffer 22a, to the slave 10 making the inquiry, via the transmitter 13 and the receiver 24. The slave 10 receiving that accept response sets the request value related to the inquiry, and sets the next request value, based on the received request value for each input point.

The random value adder 21e attaches a random value to an input point to which no request value has been set in the request value buffer 22a, after all of the multiple slaves 10 complete setting of request values. The request value for each input point in the request value buffer 22a, having the random value attached thereto by the random value adder 21e, is sent to the slaves 10, via the transmitter 13 and the receiver 24. In response to receiving request value for each input point in the request value buffer 22a, having the random value attached thereto, from the master 20, each of the slaves 10 makes the failure simulator 11b execute a failure simulation, based on the received request value for each input point. At this time, the failure simulator 11b executes a failure simulation on a divided circuit corresponding to that slave 10, and obtains response value as an expected value when the request value is entered to that divided circuit. The expected value obtained by the failure simulator 11b is sent to the master 20 via the transmitter 23 and the receiver 14, together with the failure detected with request value, i.e., the information about the detected failure.

The merger 21f merges expected values for the divided circuits, received from the slaves 10. The expected value merged by the merger 21f, and the request value for each input point in the request value buffer 22a, having the random value attached thereto, are stored in the test pattern database 26, as the entire examined circuit test pattern.

### (2-2) Operation of Test Pattern Generator of the Present Embodiment

Next, an operation of the test pattern generator 1 configured as described above will be described with reference to FIGS. 5 to 8, referring to the flowchart depicted in FIG. 4 (Steps S10 to S30).

Firstly, the circuit divider 21a in the master 20 divides an examined circuit stored in a circuit database 25 into multiple circuits, as set forth above with reference to FIGS. 2 and 3 (Step S10).

Here, the detailed steps in the circuit division processing by the circuit divider 21a will be described referring to the flowchart depicted in FIG. 5 (Steps S31 to S35, S341 to S344, S351 to S353).

The circuit divider 21a obtains an circuit model of the examined circuit as a whole, from the circuit database 25 (Step S31), and divides an observation point scan latch in an examined circuit, an output state of which is to be observed as an expected value, into multiple latch groups. One of the divided circuits with ID=1, 2, . . . , n (n is a division count) is provided to one latch group (Step S32).

Thereafter, on the latch group with ID=1, 2, . . . , n, the following divided circuit trace processing (Step S34) is executed, and the following divided circuit output processing (Step S35) is also executed. After the divided circuit trace processing and the divided circuit output processing are executed on all of the latch groups (the YES route from Step S33), the circuit divider 21a terminates the circuit division processing.

In the divided circuit trace processing (Step S34), initially, the circuit divider 21a performs initialization for setting the latch group with ID=i (i=1, 2, . . . , n) to the start point set at the level L=1 (Step S341). After the initialization, the following processing (Steps S343 and S344) is performed for the levels L=1, 2, and 3. After the following processing (Steps S343 and S344) is performed for the levels L=1, 2, and 3 (the YES route from Step S342), the divided circuit trace processing is terminated (Step S34).

In Step S343, the circuit divider 21a initiates a back trace from start point set at the level L. When L=3, no back trace from the data-in terminal Din in the scan latch is executed.

In Step S344, the circuit divider 21a back-traces for one stage from the start point set at the level L to the previous-stage logic. The circuit divider 21a then sets the scan latch attained in the back trace to the start point set at the next level L=i+1 and the marks the trace range.

In the divided circuit output processing (Step S35), the circuit divider 21a adjusts the scan-out attributes (Step S351). Specifically, scan-out attributes of scan latches other than the level L=1 are deleted. The circuit divider 21a then performs boundary processing (Step S352). More specifically, the circuit divider 21a looks up the trace range marked in Step S344, and terminates the boundary between the trace and the non-trace to a constant-uncontrollable value (Const-U). Thereafter, the circuit divider 21a outputs the divided circuit model with ID=i (Step S353), and moves to the processing in Step S33.

With the circuit division processing described above, in order to support a delay test with a double pulse (WDFT), a back trace is executed, from each of the divided latch groups, for two stages for the data lines, and three stages for the control lines, as depicted in FIGS. 2 and 3. A divided circuit of the examined circuit is obtained for each divided latch group. The information about a divided circuit is stored in a divided circuit database 15 in a slave 10 which is assigned to process that circuit.

Thereafter, the master 20 clears the request value buffer 22a (Step S11), and then sends an ATPG start signal for instructing the ATPGs 11a in all of the slaves 10 to start generation of a request value (Step S12).

The ATPG 11a in each slave 10, in response to receiving the ATPG start signal from the master 20 via the receiver 14, starts generation of a request value, by selecting a primary failure in the corresponding divided circuit (the “With Failure” route from Step S21). The ATPG 11a generates a request value to be set to the input point in that divided circuit for detecting the selected primary failure (Step S22), and executes a dynamic compaction. In the dynamic compaction, a secondary failure is selected (the “With Failure” route from Step S23) under the condition of the setting of the request value for detecting the primary failure, and a request value to be set to the input point in the divided circuit for detecting the selected secondary failure is generated or created (Step S24). If the request value is successfully generated for the secondary failure, a flag indicating the success in generating that request value is set.

Once the request value request is generated in Step S24, synchronization processing (Steps S25 and S14) is performed between the slaves 10 and the master 20.

Here, synchronization processing of request values (Steps S14 and S25) depicted in FIG. 4 will be described with reference to the flowchart depicted in FIG. 6 (Steps S141 to S147 and S251 to S254).

When the request value is generated in Step S24, a slave 10 clears the state related to the detection of that failure from the divided circuit model. Then the slave 10 inquires the decision maker 21d in the master 20 as to whether or not a conflict occurs, via the transmitter 13 and the receiver 24 (Step S251). As used herein, a conflict refers to a situation wherein a request value that is generated in Step S24, i.e., a request value that is set to a point by an ATPG 11a in a slave 10 differs from a request value set by another slave 10 to that input point.

When the master 20 receives the inquiry about a conflict of the request value to be set from the slave 10 at the receiver 24 (Step S141), the decision maker 21d checks the request value related to the inquiry against the request values stored in the request value buffer 22a (Step S142). As set forth above, the decision maker 21d checks a bit corresponding to the input point, to which the request value related to the inquiry is set, in the request value buffer 22a, and compares the request value stored in that bit, against the request value related to the inquiry.

If the decision maker 21d determines that a conflict occurs (the YES route from Step S143), the decision maker 21d does not update the request value buffer 22a and sets a value indicating that a conflict occurs (reject) to a response value for the slave 10 (Step S144). The response value having a value of “reject” set thereto is sent to the slave 10 making the inquiry, via the transmitter 13 and the receiver 24 (Step S145). After sending the response value, the master 20 returns to the processing in Step S13, which will be described later.

The slave 10 receives the response value from the master 20 at the receiver 24 (Step S252). If “reject” is set in the received response value (the NO route from Step S253), the slave 10 (the ATPG 11a) stops setting that request value and moves to the processing in Step S23. At this time, for selecting the current secondary failure as a target (selected target) in a subsequent dynamic compaction, the slave 10 clears the flag indicating the success of generation of the request value for that secondary failure.

Otherwise, if the decision maker 21d determines that no conflict occurs (the NO route from Step S143), a value indicating that no conflict occurs (accept) and the request value for each input point stored in the request value buffer 22a are set to a response value for the slave 10 (Step S146). Further, the request value related to the inquiry is reflected to the corresponding request value stored in the request value buffer 22a. In other words, the request value related to the inquiry is added to the request value buffer 22a, as a request value set to the corresponding input point (Step S147). The response value having a value of “accept” and the request value for each input point stored in the request value buffer 22a set thereto is sent to the slave 10 making the inquiry, via the transmitter 13 and the receiver 24 (Step S145). After sending the response value, the master 20 returns to the processing in Step S13, which will be described later.

The slave 10 receives the response value from the master 20 at the receiver 24 (Step S252). If “accept” is set in the received response value (the YES route from Step S253), the slave 10 (the ATPG 11a) sets the request value related to the inquiry (Step S254). In other words, the slave 10 (the ATPG 11a) implies the state of the divided circuit model, using the request value for each input point, that is sent back from the master 20, and moves to the processing in Step S23.

In the ATPG 11a, by repeating the processing in Steps S23 to S25, request values for detecting the secondary failure are superimposed, under the condition of the setting of the request value for detecting the primary failure. If there is no secondary failure to be superimposed any more, that is, there is no secondary failure that can be selected (the “No Failure” route from Step S23), the ATPG 11a terminates the processing and sends an ATPG end signal to the master 120 (Step S26).

In the meantime, in the master 20, after sending the ATPG start signal, the ATPG controller 21b waits until ATPG end signals are sent from all of the slaves 10 (Step S13). While waiting for ATPG end signals being sent from all of the slaves 10, the ATPG controller 21b performs synchronization processing on the request values, in response to an inquiry from the respective slaves 10 (Step S14).

After the ATPG controller 21b receives an ATPG end signal from all of the slaves 10 via the receiver 24 (the YES route from Step S13), the random value adder 21e attaches a random value to an input point to which no request value has been set in the request value buffer 22a (Step S16). The request value for each input point in the request value buffer 22a, having the random value attached thereto by the random value adder 21e, i.e., the request value the conflict of which is suppressed (conflict-suppressed request value), is sent to the slaves 10, via the transmitter 13 and the receiver 24. Then, the failure simulator controller 21c is activated, and the failure simulator controller 21c sends a start signal to the failure simulators 11b in all of the slaves 10 to instruct a start of a failure simulation (Step S17).

Each slave 10 initiates a failure simulation, in response to receiving the conflict-suppressed request value and the start signal for a failure simulation from the master 20. In other words, the failure simulator 11b gives conflict-suppressed request value from the master 20 to an input point in the divided circuit to perform the simulation, thereby obtaining an expected value that is a response for the divided circuit (Step S28). The expected value obtained by the failure simulator 11b is sent to the master 20 via the transmitter 23 and the receiver 14, together with the information about the failure detected with request value (Step S29). After sending the expected value and the detected failure, the failure simulator 11b terminates the processing, and sends a failure simulation end signal to the master 20 (Step S30).

In the master 20, after sending the failure simulation start signal, the failure simulator controller 21c waits until failure simulation end signals are sent from all of the slaves 10 (Step S18). Once receiving failure simulation end signals from all of the slaves 10 (the YES route from Step S18), the failure simulator controller 21c terminates the processing, and the merger 21f is activated. In response, the merger 21f merges expected values for the divided circuits, received from the slaves 10. The merger 21f stores the merged expected value, and the request value for each input point in the request value buffer 22a, having the random value attached thereto, in the test pattern database 26, as the entire examined circuit test pattern (Step S19). The master 20 returns to Step S11 to repeat processing as described above until an end condition is met (until the determination in Step S20 produces YES).

If the ATPG 11a in each slave 10 generates request values for all failures assigned to the divided circuit and there is no failure which can be selected (the “No Failure” route from Step S21), the slave 10 performs the following operation. More specifically, the slave 10 sends a complete signal to the master 20, via the transmitter 13 and the receiver 24 (Step S27). At this time, rather than stopping processing of the slave as in the test pattern generator 100 depicted in FIGS. 9 and 10, the slave 10 only stops processing of the ATPG 11a and continues to start of failure simulation.

Further, in response to receiving the complete signal, rather than detaching the slave 10 as in the test pattern generator 100 depicted in FIGS. 9 and 10, the master 20 waits until complete signals are sent from all of the slaves 10 (Step S15). After receiving complete signal from all of the slaves 10 (the YES route from Step S15), the master 20 activates the failure simulator controller 21c to perform the processing in Steps S17 to S20.

With this operation, in a slave 10 which has no more failure to be selected, the processing for generating request values by the ATPG 11a is skipped, while continuing the failure simulation processing to obtain an expected value.

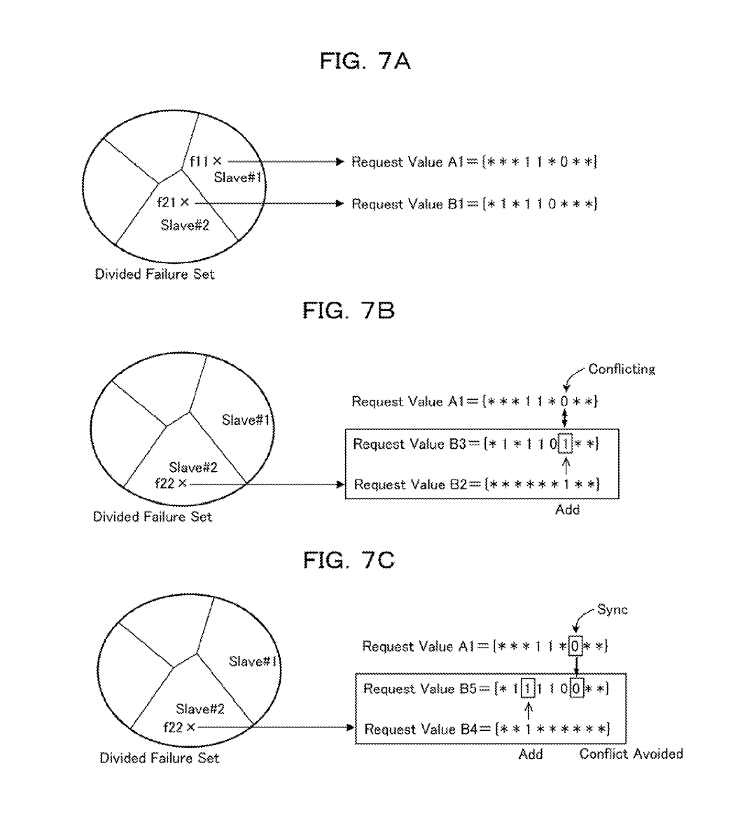

Next, an example of an operation of the test pattern generator 1 of the present embodiment will be discussed in a concrete manner in a comparison with an operation of a conventional technique, with reference to FIGS. 7A to 7C.

FIG. 7A depicts an example wherein two slaves 10 (Slave #1 and Slave #2) generate request values for failures f11 and f21 in a divided failure set. For example, in FIG. 7A, Slave #1 generates a request value A1={***11*0**} for the failure f11, while Slave #2 generates a request value B1={*1110***} for the failure f21.

Here, “*” represents a bit (input point) to which no request value has been set.

In FIG. 7A, no conflict occurs between the request value Al for the failure f11 and the request value B1 for the failure f21. Accordingly, the request value {*1*1100**} obtained by merging the request value A1 and the request value B1 can be used as a test pattern, and no increase in the test pattern count occurs.

FIG. 7B depicts a situation wherein Slave #1 and Slave #2 generate request values Al and B1 depicted in FIG. 7A, respectively, in the typical test pattern generator 100 depicted in FIGS. 9 and 10, and then Slave #2 generates a request value B2 for a secondary failure f22. Here, Slave #2 generates a request value B2={******1**} for the failure f22.

In this case, Slave #2 performing parallel processing fully independently from Slave #1 superimposes the request value B2 to the request value B1 to generate a request value B3={*1*1101**}. Hence, the request value B3={*11101**} generated by Slave #2 and the request value A1={***11*0**} generated by the different Slave #1 have request values at the seventh bit from the left, and thus a conflict occurs. Accordingly, the request values Al and B3 cannot be merged, which causes an increase in the test pattern count.

FIG. 7C depicts a situation wherein, in the test pattern generator 1 of the present embodiment, after Slave #1 generates the request value A1 depicted in FIG. 7A, Slave #2 generates the request value B1 depicted in FIG. 7A, and then Slave #2 generates request value B4 for the secondary failure f22.

In this case, at the time when Slave #1 generates the request value Al depicted in FIG. 7A, the request value {***11*0**}, which is the same as the value of the request value A1, is stored in the request value buffer 22a in the master 20. Thereafter, when Slave #2 generates the request value B1 depicted in FIG. 7A, Slave #2 makes an inquiry to the master 20 about the request value B1. In this case, as described above, no conflict occurs between the request value A1 and the request value B1. Accordingly, the request value stored in the request value buffer 22a is reflected to the request value B1, and the request value B1 is reflected to the request value buffer 22a. More specifically, the request value in the request value buffer 22a is changed to {*11100**}, and the request value {*1*1100**} is also sent back from the master 20 to Slave #2 and synchronization of request values is performed.

If Slave #2 generates a request value B4={**1******} for the secondary failure f22 when the synchronized request value is {*11100**}, a request value B5={*111100**} is generated by adding the request value B4={**1******} to the synchronized request value {*11100**}. When an inquiry is made to the master 20 about the request value B5, no conflict occurs between the request value {*1*1100**} in the request value buffer 22a and the request value B5. Accordingly, the request value in the request value buffer 22a is changed to {*111100**}, and the request value sent back from the master 20 to Slave #2 is also {*111100**} and synchronization of request values is performed.

In the manner as described above, request values generated by slaves 10 are synchronized (matched to the same value) by the master 20 (the request value buffer 22a). In other words, since a request value for a detectable failure is generated while request values from other slaves 10 being synchronized, a request value can be generated while minimizing a conflict, which can suppress an increase in the test pattern count.

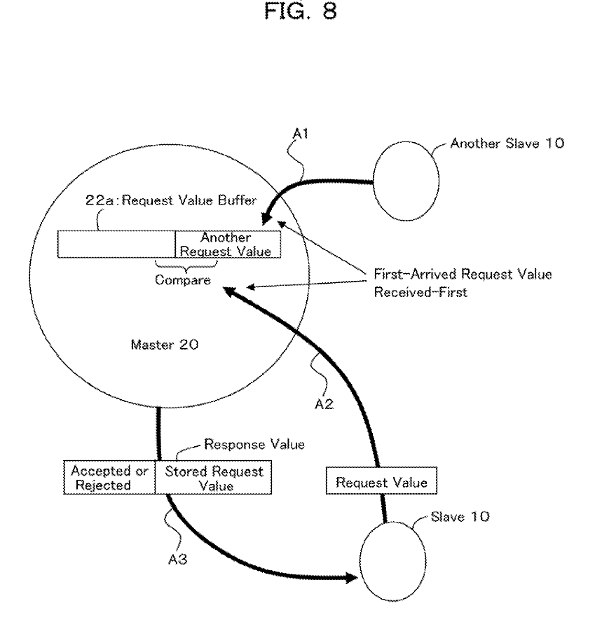

In the test pattern generator 1 of the present embodiment, no priority is set among transmissions of request values (inquiries) from slaves 10 to the master 20, as depicted in FIG. 8, and the request values are sent asynchronously. Hence, reception of request values and setting of a request value into the request value buffer 22a by the master 20 are done on a first-come, first-served basis (refers to Arrows A1 and A2). FIG. 8 is a diagram illustrating an asynchronous communication of request values between slaves 10 and the master 20 in the present embodiment.

In FIG. 8, a slave 10 makes an inquiry for request value to the master 20 (refer to Arrow A2), after another slave 10 accesses the master 20 (refer to Arrow A1) and the request value from that slave 10 is reflected to the request value buffer 22a. In response to the inquiry from the slave 10, the request value related to the inquiry is checked against the request value in the request value buffer 22a. If a conflict occurs in this check, a response value indicating reject is returned to the slave 10 (refer to Arrow A3). Otherwise, if no conflict occurs, a response value indicating accept and the request value stored in the request value buffer 22a is returned to the slave 10 (refer to Arrow A3).

### (2-3) Advantageous Effects of Test Pattern Generator of the Present Embodiment

As described above, the test pattern generator 1 of the present embodiment avoids any conflict of request values to be set to a common input point among divided circuits, by communicating between the master 20 and a slave 10 during generation of request values by the ATPGs 11a, rather than allowing the slave 10 to operate fully independently.

More specifically, request values are synchronized (matched to the same value) among multiple slaves 10 by means of the request value buffer 22a in the master 20. That is, request values of the slaves 10 are synchronized (matched to the same value) via the request value buffer 22a. Hence, even when test patterns are generated in parallel processing by multiple slaves 10, a circuit state that is comparable to a test pattern generation in a single computing device is maintained in the request value buffer 22a, which suppresses any increase in the test pattern count due to the parallel processing. Without causing any overhead of an increase in the test pattern count, load balancing for reducing memory consumption of each computer and faster test pattern generation by the parallel processing can be achieved by multiple computers (computing devices).

Further, the test pattern generator 1 of the present embodiment, in a slave 10 which has no more failure to be selected, skips request value generation processing by the ATPG 11a, while continuing the failure simulation processing to obtain an expected value, in order to support a pattern compaction circuit using the MISR. This prevents any increase in the test pattern count due to masking of undefined values.

Further, while random value attachment processing is executed in each slave 110 in the typical the test pattern generator 100, as depicted in Step A25 in FIG. 10, the processing is done solely by the random value adder 21e in the master 20 in the test pattern generator 1 of the present embodiment (refer to Step S16 in FIG. 4). This can help to reduce the load of each slave 10.

### (3) Others

While preferred embodiments of the invention have been described in detailed above, it should be understood that these are exemplary of the invention and are not to be considered as limiting. Any modifications and variations can be made without departing from the spirit of the invention.

Note that all or a part of the functions as the ATPG 11a and the failure simulator 11b in the above-described slaves 10 and the functions as the circuit divider 21a, the ATPG controller 21b, the failure simulator controller 21c, the decision maker 21d, the random value adder 21e, and the merger 21f in the above-described the master 20 are embodied by a computer (such as a CPU, an information processing apparatus, various types of devices) by executing a certain application program (test pattern generation program).

Such a program is provided in the form of a record on computer readable storage medium, for example, a flexible disk, CDs (such as a CD-ROM, CD-R, a CD-RW), DVDs (such as a DVD-ROM, a DVD-RAM, a DVD-R, a DVD-RW, a DVD+R, a DVD+RW), and Blu-ray disks. In this case, the computer reads the program from that storage medium and uses that program after transferring it to the internal storage apparatus or external storage apparatus or the like.

Here, the term “computer” may be a concept including hardware and an OS (operating system), and may refer to hardware that operates under the control of the OS. Alternatively, when an application program alone can make the hardware to be operated without requiring an OS, the hardware itself may represent a computer. The hardware may include, at least a microprocessor, such as a CPU, and device to read a computer program stored on a storage medium. The test pattern generation program includes a program code to embody the functions as the ATPG 11a, the failure simulator 11b, the circuit divider 21a, the ATPG controller 21b, the failure simulator controller 21c, the decision maker 21d, the random value adder 21e, and the merger 21f in such a computer. In addition, a part of the functions may be embodied by the OS, rather than the application program.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment(s) of the present invention has(have) been described in detail, it should be understood that the various changes, substitutions, and alterations could be made hereto without departing from the spirit and scope of the invention.

What is claimed is:

1. A test pattern generator that generates a test pattern for each of a plurality of divided circuits defined by dividing an integrated circuit into a plurality of circuits using a plurality of computing devices, the test pattern generator comprising:
a plurality of first computing devices, each generating a test pattern for one of the divided circuits;
a second computing device that controls the generation of the test patterns by the plurality of first computing devices, and comprises a request value buffer for storing a request value for each input point used for detecting a failure in an examined circuit in each divided circuit,
the second computing device determining whether or not a conflict occurs wherein at least two of the plurality of first computing devices set different request values to an input point to which a request value is to be set, based on the request value stored in the request value buffer, and
when it is determined by the second computing device that a conflict occurs wherein one of the plurality of first computing devices is about to set a request value different from a request value that is set to that input point by another first computing device, the one of the first computing devices stops setting the request value.

2. The test pattern generator according to claim 1, wherein the one of first computing device, upon setting the request value to an input point in each divided circuit, inquires the second computing device as to whether or not a conflict occurs wherein the one of the plurality of first computing devices is about to set a request value different from a request value that is set to that input point by another first computing device, and
in response to the inquiry from that first computing device, the second computing device makes a decision for the inquiry, based on the request value stored in the request value buffer.

3. The test pattern generator according to claim 2, wherein in response to the inquiry about a conflict from the first computing device, the second computing device,
when no conflict occurs wherein the request value related to the inquiry from the one of the first computing devices is different from a corresponding request value stored in the request value buffer, reflects the request value related to the inquiry to the corresponding request value stored in the request value buffer, and sends a response to the inquiry indicating that no conflict occurs, to the one of the first computing devices, and
when a conflict occurs wherein the request value related to the inquiry from the one of the first computing devices is different from the corresponding request value stored in the request value buffer, sends a response to the inquiry indicating that a conflict occurs, to the one of the first computing devices.

4. The test pattern generator according to claim 3, wherein the one of the first computing devices sets the request value related to the inquiry, in response to receiving the response to the inquiry indicating that no conflict occurs.

5. The test pattern generator according to claim 3, wherein the second computing device, when no conflict occurs, sends the response to the inquiry indicating that no conflict occurs, to the one of the first computing devices, and sends the request value for each input point stored in the request value buffer, to the one of the first computing devices, and
the one of the first computing devices, in response to receiving the request value for each input point stored in the request value buffer, sets a subsequent request value based on the received request value for each input point.

6. The test pattern generator according to claim 1, wherein the second computing device, when the plurality of first computing devices complete to set the request values, attaches a random value to at least one input point to which no request value is set in the request value buffer, and then sends the request value for each input point having the random value attached thereto in the request value buffer, to the plurality of first computing devices, and
each of the plurality of first computing devices, in response to receiving the request value for each input point having the random value attached thereto in the request value buffer from the second computing device, performs a failure simulation on the divided circuit assigned to the each first computing device, based on the received request value for each input point, and obtains a response value as an expected value when the request value is entered to that divided circuit.

7. The test pattern generator according to claim 1, wherein the second computing device divides a scan latch in the integrated circuit, an output state of which is to be observed as an expected value, into a plurality of latch groups, divides the integrated circuit into the plurality of circuits each corresponding to the plurality of latch groups by back-tracing from each divided latch group, and assigns the plurality of divided circuits to the respective plurality of first computing devices.

8. The test pattern generator according to claim 7, wherein the second computing device performs back traces for at least two stages from the each divided latch group, in order to support a delay test with a double pulse.

9. A method of generating a test pattern for each of a plurality of divided circuits defined by dividing an integrated circuit, using a plurality of first computing devices, each generating a test pattern for one of the divided circuits, and a second computing device that controls the generation of the test patterns by the plurality of first computing devices, the method comprising:
the second computing device storing, in a request value buffer, a request value for each input point used for detecting a failure in an examined circuit in each divided circuit, and determining whether or not a conflict occurs wherein at least two of the plurality of first computing devices set different request values to an input point to which a request value is to be set, based on the request value stored in the request value buffer; and
when it is determined by the second computing device that a conflict occurs wherein one of the plurality of first computing devices is about to set a request value different from a request value that is set to that input point by another first computing device, the one of the first computing devices stopping setting the request value.

10. The method of generating a test pattern according to claim 9, wherein the one of first computing device, upon setting the request value to an input point in each divided circuit, inquiring the second computing device as to whether or not a conflict occurs wherein the one of the plurality of first computing devices is about to set a request value different from a request value that is set to that input point by another first computing device, and
in response to the inquiry from that first computing device, the second computing device making a decision for the inquiry, based on the request value stored in the request value buffer.

11. The method of generating a test pattern according to claim 10, wherein in response to the inquiry about a conflict from the first computing device, the second computing device,
when no conflict occurs wherein the request value related to the inquiry from the one of the first computing devices is different from a corresponding request value stored in the request value buffer, reflecting the request value related to the inquiry to the corresponding request value stored in the request value buffer, and sending a response to the inquiry indicating that no conflict occurs, to the one of the first computing devices, and
when a conflict occurs wherein the request value related to the inquiry from the one of the first computing devices is different from the corresponding request value stored in the request value buffer, sending a response to the inquiry indicating that a conflict occurs, to the one of the first computing devices.

12. The method of generating a test pattern according to claim 11, wherein the one of the first computing devices setting the request value related to the inquiry, in response to receiving the response to the inquiry indicating that no conflict occurs.

13. The method of generating a test pattern according to claim 11, wherein the second computing device, when no conflict occurs, sending the response to the inquiry indicating that no conflict occurs, to the one of the first computing devices, and sending the request value for each input point stored in the request value buffer, to the one of the first computing devices, and
the one of the first computing devices, in response to receiving the request value for each input point stored in the request value buffer, setting a subsequent request value based on the received request value for each input point.

14. The method of generating a test pattern according to claim 9, wherein the second computing device, when the plurality of first computing devices complete to set the request values, attaching a random value to at least one input point to which no request value is set in the request value buffer, and then sending the request value for each input point having the random value attached thereto in the request value buffer, to the plurality of first computing devices, and
each of the plurality of first computing devices, in response to receiving the request value for each input point having the random value attached thereto in the request value buffer from the second computing device, performing a failure simulation on the divided circuit assigned to the each first computing device, based on the received request value for each input point, and obtaining a response value as an expected value when the request value is entered to that divided circuit.

15. The method of generating a test pattern according to claim 9, wherein the second computing device dividing a scan latch in the integrated circuit, an output state of which is to be observed as an expected value, into a plurality of latch groups, dividing the integrated circuit into the plurality of circuits each corresponding to the plurality of latch groups by back-tracing from each divided latch group, and assigning the plurality of divided circuits to the respective plurality of first computing devices.

16. The method of generating a test pattern according to claim 15, wherein the second computing device performing back traces for at least two stages from the each divided latch group, in order to support a delay test with a double pulse.

17. A computer readable storage medium having a test generation program stored thereon, that makes a computer to function, in order to generate a test pattern for each of a plurality of divided circuits defined by dividing an integrated circuit, as one of a plurality of first computing devices, each generating a test pattern for one of the divided circuits, or a second computing device that controls the generation of the test patterns by the plurality of first computing devices, the program making the computer functioning as the second computing device:
store, in a request value buffer, a request value for each input point used for detecting a failure in an examined circuit in each divided circuit, and determine whether or not a conflict occurs wherein at least two of the plurality of first computing devices set different request values to an input point to which a request value is to be set, based on the request value stored in the request value buffer; and
the program makes the computer functioning as the one of the first computing devices, when it is determined by the second computing device that a conflict occurs wherein one of the plurality of first computing devices is about to set a request value different from a request value that is set to that input point by another first computing device, stop setting the request value.

18. The computer readable storage medium according to claim 17 having a test generation program stored thereon, wherein the program makes the computer functioning as the one of the first computing devices inquiry the second computing device as to whether or not a conflict occurs wherein the one of the plurality of first computing devices is about to set a request value different from a request value that is set to that input point by another first computing device, upon setting the request value to an input point in each divided circuit, and
the program makes the computer functioning as the second computing device, in response to the inquiry from that first computing device, make a decision for the inquiry, based on the request value stored in the request value buffer.

19. The computer readable storage medium according to claim 18 having a test generation program stored thereon, wherein the program makes the computer functioning as the second computing device, in response to the inquiry about a conflict from the first computing device:
when no conflict occurs wherein the request value related to the inquiry from the one of the first computing devices is different from a corresponding request value stored in the request value buffer, reflect the request value related to the inquiry to the corresponding request value stored in the request value buffer, and send a response to the inquiry indicating that no conflict occurs, to the one of the first computing devices, and
when a conflict occurs wherein the request value related to the inquiry from the one of the first computing devices is different from the corresponding request value stored in the request value buffer, send a response to the inquiry indicating that a conflict occurs, to the one of the first computing devices.

20. The computer readable storage medium according to claim 19 having a test generation program stored thereon, wherein the program makes the computer functioning as the second computing device, when no conflict occurs, send the response to the inquiry indicating that no conflict occurs, to the one of the first computing devices, and send the request value for each input point stored in the request value buffer, to the one of the first computing devices, and
the program makes the computer functioning as the one of the first computing devices, in response to receiving the request value for each input point stored in the request value buffer, set a subsequent request value based on the received request value for each input point.
